(19) United States
(12) Patent Application Publication
(10) Pub. No.: US 2021/0351319 A1
(43) Pub. Date: Nov. 11, 2021

(54) Production Method for a Component

(71) Applicant: OSRAM OLED GmbH, Regensburg (DE)

(72) Inventors: Ralf Wombacher, Burglengenfeld (DE); Josef Hirn, Schwandorf (DE); Markus Boß, Regensburg (DE)

(21) Appl. No.: 17/277,764

(22) PCT Filed: Sep. 12, 2019
(86) PCT No.: PCT/EP2019/074371

§ 371 Date: Mar. 19, 2021

(30) Foreign Application Priority Data
Sep. 19, 2018 (DE) 10 2018 123 031.1

(51) Int. Cl. H01L 33/00; H01L 25/16; H05K 1/18; H01L 33/48; H01L 33/62

(52) U.S. Cl. CPC H01L 33/0093; H01L 25/167; H01L 2933/0066; H01L 33/486; H01L 33/62; H05K 1/189

(57) ABSTRACT

In an embodiment a method for manufacturing optoelectronic components includes providing a metal sheet, milling the metal sheet, structuring the metal sheet into a lead frame blank with the intermediate pieces, applying a plurality of semiconductor devices to the intermediate pieces and separating to form the components. Each components may include an optoelectronic semiconductor device including at least two electrical contact surfaces on an assembly side, a lead frame base and electrical connection surfaces for external electrical contacting of the semiconductor device, wherein each base comprises at least two metallic intermediate pieces, wherein each of the intermediate pieces is fastened directly to one of the contact surfaces, and wherein the intermediate pieces are each L-shaped or T-shaped.

This patent application is a national phase filing under section 371 of PCT/EP2019/074371, filed Sep. 12, 2019, which claims the priority of German patent application 102018123031.1, filed Sep. 19, 2018, each of which is incorporated herein by reference in its entirety.

### TECHNICAL FIELD

A method of manufacturing an optoelectronic component is specified.

### SUMMARY

Embodiments provide a method of manufacturing an optoelectronic component which can be used in many applications with minor design adaptations.

According to at least one embodiment, the manufacturing method is used to manufacture an optoelectronic component, or component for short. Features of the manufacturing method are therefore also disclosed for the component and vice versa.

In particular, the component comprises an optoelectronic semiconductor device and a base, also referred to as an interposer, which is formed as a lead frame. By means of milling, the base is shaped such that the base can be workable by means of punching. Thus, due to the base optoelectronic semiconductor devices can be used in different applications without design adaptation.

According to at least one embodiment, the component comprises an optoelectronic semiconductor device. The semiconductor device is configured for radiation generation or radiation detection. For example, the optoelectronic semiconductor device is a light-emitting diode, a photodetector or a laser diode.

According to at least one embodiment, the semiconductor device comprises an assembly side. In particular, the semiconductor device is surface mountable, so that an electrical as well as mechanical mounting of the semiconductor device is performed at the assembly side. Preferably, the assembly side is opposite of a light entry side or a light exit side of the semiconductor device.

According to at least one embodiment, the semiconductor device comprises two or more than two electrical contact surfaces at the assembly side. The electrical contact surfaces are preferably an integral part of the semiconductor device. The contact surfaces are configured, for example, for mounting by means of soldering or by means of electrically conductive bonding.

According to at least one embodiment, the component comprises a base, also referred to as an interposer. The base is a lead frame. Thus, the base is a metallic base by means of which a thickness of the component can be adjusted.

According to at least one embodiment, the base comprises two or more than two metallic intermediate pieces. Within the base, the intermediate pieces are preferably not electrically connected to each other. That is, the intermediate pieces may be separate metallic components that are not directly connected to each other.

According to at least one embodiment, each of the intermediate pieces is fastened directly to one of the contact surfaces of the semiconductor device. That is, there may be a one-to-one correspondence between the intermediate parts and the contact surfaces.

The fact that the intermediate pieces are fastened directly to the contact surfaces means in particular that there is only one bonding agent between the intermediate pieces and the contact surfaces. The base is fastened to the semiconductor device via such a bonding agent. Such a bonding agent is, for example, a solder or an electrically conductive adhesive. A thickness of the bonding agent and thus a distance between the intermediate pieces and the associated contact surfaces is, for example, at most 10 μm or 5 μm or 2 μm.

According to at least one embodiment, the intermediate pieces comprise electrical connection surfaces for external electrical contacting of the semiconductor device. The connection surfaces are preferably configured for solder assembly or for electrically conductive bonding.

According to at least one embodiment, the connection surfaces are located on bottom sides of the intermediate pieces facing away from the semiconductor device. In particular, the bottom sides of the intermediate pieces are each formed as connection surfaces over their entire surface. It is possible that all connection surfaces of the component are located on the bottom sides of the intermediate pieces. Thus, the component is preferably surface mountable in the same way as the semiconductor device.

According to at least one embodiment, a quotient of a thickness of the intermediate pieces and a distance between the intermediate pieces in a direction parallel to the assembly side is at least 2 or 2.5 or 3 or 4. Alternatively or additionally, this quotient is at most 30 or 20 or 10. In other words, a distance between the intermediate pieces is significantly smaller than a thickness of the intermediate pieces. The intermediate pieces preferably all comprise the same thickness, within manufacturing tolerances.

In at least one embodiment, the component comprises an optoelectronic semiconductor device comprising at least two electrical contact surfaces on an assembly side. A base of the component is a lead frame. The base comprises at least two metallic intermediate pieces. Each of the intermediate pieces is directly attached to one of the contact surfaces. Electrical connection surfaces for external electrical contacting of the semiconductor device are formed by bottom sides of the intermediate pieces facing away from the semiconductor device. A quotient of a thickness of the intermediate pieces and a distance between the intermediate pieces in the direction parallel to the assembly side is particularly preferably between 3 and 20 inclusive.

Often, several different electronic components in devices such as cell phones are mounted, for example soldered, on a common rigid or flexible printed circuit board. Since these electronic components generally comprise different component heights, this difference in height must be compensated. This can be done using so-called interposers. By varying the thickness of the interposer, this also has the advantage of allowing the same electronic components to be used in different models or devices.

The following requirements are in particular placed on the interposer: Solderability, high thermal conductivity, low thickness tolerances. As standard, such interposers are formed by printed circuit boards, PCBs for short, and are usually manufactured using two-layer or multilayer technology. However, such interposers, which are manufactured in PCB technology, comprise comparatively large thickness tolerances, so that the necessary accuracy requirements for the application of PCBs as interposers often cannot be met. In addition, PCB interposers comprise a comparatively low thermal conductivity.

In the component described herein, the base is used as the interposer.

In one embodiment, the base is designed as a lead frame, in particular a copper lead frame, especially made of a bulk material. Copper lead frames or lead frames in general can be manufactured with very small thickness tolerances, whereby a high accuracy of an overall thickness of the component can be achieved. Furthermore, lead frames, especially made of copper, comprise a high thermal conductivity. In addition, lead frames made of copper, for example, are inexpensive to manufacture, especially since stamped and metallized lead frames can be used. Since copper comprises a very high thermal conductivity of about 400 W/m·K, efficient heat dissipation of the semiconductor devices is possible with the bases described herein.

For example, small thickness tolerances can be realized by using a sheet, such as a rolled copper sheet, for the base. Milling also makes it possible for the intermediate pieces to comprise cross-sections that deviate from a rectangular cross-section when viewed perpendicular to the assembly side. In particular, the intermediate pieces can comprise a recess at a joint between the intermediate pieces.

Via such a recess, it is possible to geometrically shape the lead frame and thus the intermediate pieces via cost-efficient punching. Thus, geometries can be achieved which show a small distance between the intermediate pieces within the component, wherein the intermediate pieces can comprise a comparatively large thickness. Over the wide possible range of thicknesses of the intermediate pieces, the base can be used for a variety of applications and the overall thickness of the component can be varied over a wide range without having to adjust the component.

In another embodiment, the base is formed by a composite lead frame. The composite lead frame comprises, as cover plate and as bottom plate, respective comparatively thin sheets which are preferably made of copper and which can be manufactured with small thickness tolerances. A gap between the cover plate and the bottom plate is increased via spacers located between them, which comprise small diameter tolerances. Thus, the base can be realized with small overall thickness tolerances.

According to at least one embodiment, side surfaces of the intermediate pieces are partially, predominantly or completely exposed. Predominantly means here and in the following a proportion of at least 50% or 65% or 80% or 90%. In particular, the side surfaces are completely free of organic materials such as plastics, in particular free of silicones and epoxides. It is possible that the side surfaces are covered to a small extent by a bonding agent of the intermediate pieces towards the contact surfaces. For example, the side surfaces may be covered to a small extent by a solder with which the base is attached to the semiconductor device.

The side surfaces may be oriented perpendicular or approximately perpendicular to the assembly side. Approximate means an angular tolerance of at most 15° or 10° or 5°.

According to at least one embodiment, the intermediate pieces are L-shaped and/or T-shaped as seen in cross-section perpendicular to the assembly side. That is, the intermediate pieces then preferably comprise a first leg directly on the assembly side in each case, from which a second leg extends in the direction away from the assembly side. The first leg and the second leg may be oriented perpendicular to each other. The corresponding L or the corresponding T is formed by these legs.

According to at least one embodiment, the distance between the intermediate pieces is at least 0.1 mm or 0.2 mm. Alternatively or additionally, this distance is at most 1 mm or 0.7 mm or 0.5 mm. In other words, the intermediate pieces are arranged comparatively close to each other.

According to at least one embodiment, the intermediate pieces are L-shaped in one or more cross-sections perpendicular to the assembly side and as seen through both intermediate pieces. That is, viewed in cross-section, the intermediate pieces may comprise at least one region of a side surface that extends in a straight line from the assembly side to the connection surfaces.

According to at least one embodiment, a quotient of the thickness of the intermediate pieces and a distance between the legs of the L's or the T's extending away from the assembly side is at least 0.4 or 0.5 or 0.7. Alternatively or additionally, this quotient is at most 4 or 3 or 2 or 1.5. In other words, the distance between the legs is approximately as large as the thickness of the intermediate pieces. This distance is preferably determined in a direction parallel to the assembly side.

According to at least one embodiment, the intermediate pieces each comprise a bottom plate and a cover plate. The bottom plate is preferably located on a side of the respective intermediate piece facing away from the semiconductor device. The connection surfaces may be formed by the bottom plates of the base. In particular, there is a one-to-one assignment between the bottom plates and the connection surfaces.

According to at least one embodiment, one or more spacers are located in a direction perpendicular to the assembly side between the bottom plates and the cover plates, respectively. By means of the at least one spacer, a distance between the associated bottom plate and the associated cover plate can be precisely adjusted. For example, the spacers are copper bodies, in particular copper balls. The spacers may comprise an outer coating, in particular a solder.

According to at least one embodiment, the optoelectronic semiconductor device comprises one or more optoelectronic semiconductor chips. The at least one semiconductor chip comprises a semiconductor layer sequence. The semiconductor layer sequence is configured to generate electromagnetic radiation such as near ultraviolet radiation, visible light, or near infrared radiation. Alternatively, at least one semiconductor chip is provided that is configured to detect radiation such as visible light or near-infrared radiation.

The semiconductor layer sequence is preferably based on a III-V compound semiconductor material. For example, the semiconductor material is a nitride compound semiconductor material such as AlnIn1-n-mGamN or a phosphide compound semiconductor material such as AlnIn1-n-mGamP or an arsenide compound semiconductor material such as AlnIn1-n-mGamAs or such as AlnGamIn1-n-mAskP1-k, wherein in each case 0≤n≤1, 0≤m≤1 and n+m≤1 as well as 0≤k<1. Preferably, for at least one layer or for all layers of the semiconductor layer sequence, 0<n≤0.8, 0.4≤m<1 and n+m≤0.95 as well as 0<k≤0.5. The semiconductor layer sequence may comprise dopants as well as additional components. For simplicity, however, only the essential constituents of the crystal lattice of the semiconductor layer sequence, i.e. Al, As, Ga, In, N or P, are specified, even if these may be partially replaced and/or supplemented by small amounts of additional substances.

In particular, the semiconductor chip is a blue light emitting LED chip based on AlInGaN. In the case of a photodetector, the semiconductor chip may also be based on another semiconductor material such as silicon or germanium.

In at least one embodiment, the method comprises the following steps, in particular in the order indicated:
A) providing a metal sheet,
B) milling the metal sheet,
C) structuring the metal sheet into a lead frame blank with the intermediate pieces,
F) applying a plurality of the semiconductor devices to the intermediate pieces, and
G) separating to form the components.

The metal sheet is in particular a metal plate or a metal foil, for example a stepped strip. The metal sheet is preferably made of copper or a copper alloy, wherein metallic coatings may be present.

According to at least one embodiment, the milling in step B) is a profile milling. This allows at least one recess or more recesses to be created in each of at least some of the intermediate pieces during milling. It is possible that only the recesses are created during milling, so that no or no significant change in thickness of the metal sheet then occurs. Alternatively, both a shaping of the recesses and an adjustment or correction of the thickness of the metal sheet as a whole may be carried out during milling.

According to at least one embodiment, the metal sheet after step B) comprises a thickness variation around a thickness according to a determination, wherein the thickness variation is at most 50 μm or 30 μm or 20 μm. The same tolerances with respect to thickness preferably also apply to the lead frame blank and/or to the lead frame compounds. In other words, the metal sheet, the lead frame blank and/or the lead frame compounds are manufactured with a small thickness tolerance. Thus, a high thickness precision is possible over one or over several batches of the produced components, especially due to the use of rolled metal sheets for the bases.

According to at least one embodiment, a step D) is carried out between steps C) and F). In step D), the lead frame blank is provided with one or more metallizations. Such metallizations are, for example, formed by successive layers of nickel, palladium and/or gold. Such metallizations preferably comprise a total thickness of at most 10 μm or 5 μm.

According to at least one embodiment, the at least one metallization is applied all around and over the entire surface of the lead frame blank or of the metal sheet or of a lead frame compound. That is, for the application of the at least one metallization, no masking or application of the metallization only selectively in places is performed. Alternatively, the metallization may be produced only locally, so that a surface of the lead frame blank, the metal sheet and/or the lead frame compound remains free of the metallization in places.

According to at least one embodiment, a step E) is carried out between steps D) and F) or between steps C) and F). In step E), the lead frame blank is divided into lead frame compounds. The lead frame compounds comprise comparatively small geometric dimensions. For example, a width of the lead frame blank is between 30 mm and 300 mm inclusive and/or a length of the lead frame compounds is, for example, at least 60 mm and/or at most 600 mm. The dividing of the lead frame blanks into the lead frame compounds is performed, for example, by a punching, sawing or laser cutting process.

According to at least one embodiment, steps B), C) and/or D) are carried out in a roll-to-roll process. Such a process is also referred to as reel-to-reel.

According to at least one embodiment, the thickness of the metal sheet and/or the lead frame blank and/or the lead frame compounds is at least 0.3 mm or 0.6 mm or 1 mm. Alternatively or additionally, this thickness is at most 5 mm or 3 mm or 2 mm. In other words, the metal sheet and thus the base with the intermediate pieces is comparatively thick.

According to at least one embodiment, the structuring in step C) is carried out by means of punching. The punching is made possible in particular by the fact that by means of milling the recesses are produced in the intermediate pieces in the region of a parting line between the adjacent intermediate pieces of a component. Alternatively, the structuring in step C) can also be carried out by means of laser cutting, by means of etching or by means of a further machining step such as sawing or milling.

In at least one embodiment, the method comprises the following steps, in particular in the order indicated:
A*) Structuring the cover plates and the bottom plates for the intermediate pieces,
C*) providing the spacers and connecting the spacers to the cover plates and the bottom plates,
F) applying a plurality of the semiconductor devices to the intermediate pieces, and
G) separating to form the components.

According to at least one embodiment, one or more molded bodies, for example of a plastic, are formed in a step B*) between steps A*) and C*). The at least one molded body mechanically connects the cover plates and the associated bottom plates of a base.

According to at least one embodiment, the at least one molded body is a part of the finished base. Alternatively, the molded body may be present only temporarily during the manufacturing process, such that no molded body is left in the base in the finished components.

The thickness tolerances mentioned above for the metal sheet preferably apply equally to the cover plates, the bottom plates and/or the diameters of the spacers.

According to at least one embodiment, the contact surfaces are applied congruently or approximately congruently to the intermediate pieces. That is, the contact surfaces and the intermediate may be of the same size or approximately the same size, as viewed in plan view on the assembly side. Approximately equal in size means in particular that the surface areas of the contact surfaces differ from the surface areas of the associated intermediate pieces by no more than a factor of 1.1 or 1.2 or 1.4, as seen in plan view on the assembly side.

Alternatively, it is possible for the connection surfaces and the contact surfaces to be specifically different in size. For example, the connection surfaces and thus the intermediate pieces can project laterally beyond the contact surfaces. In this case, the intermediate pieces may also project laterally beyond the semiconductor device.

According to at least one embodiment, the components are applied to an external carrier after step G) in a step H). This application is preferably carried out by means of surface mounting and thus by means of soldering. Alternatively, electrically conductive bonding can be used. The external carrier is, for example, a rigid printed circuit board or a flexible printed circuit board.

According to at least one embodiment, at least one further semiconductor device is applied to the external carrier in addition to the at least one component. The further semiconductor device is, for example, a memory component or an integrated circuit, IC for short. Furthermore, it is possible that the further semiconductor device is an optoelectronic semiconductor device, for example a CCD chip or a color sensor.

According to at least one embodiment, the component is as thick as the further semiconductor device due to the base. This applies in particular with a tolerance of at most 40 μm or 20 μm or 10 μm, especially in a direction perpendicular to the assembly side of the semiconductor device. It is thus possible for the at least one semiconductor device and the at least one further semiconductor device to be flush, for example, with a housing of a device such as a cell phone. Furthermore, it is possible to place a further component such as an optical component downstream of the semiconductor device and the further semiconductor device with a high precision.

According to at least one embodiment, milling in step B) is performed from only one side of the metal sheet. Alternatively, double-sided milling is performed from two main sides of the metal sheet.

Furthermore, it is possible that in step B) the metal sheet is also cut to a desired width and optionally also to a specific length.

According to at least one embodiment, milling traces are still visible on the intermediate pieces after step G). The milling traces may be partially or completely covered by a metallization. However, since the metallization preferably comprises only a small thickness, the milling traces may be overmolded by the metallization true to shape. In this case, it is possible to detect the milling traces even in the metallization. Alternatively, it is possible to detect the milling traces by removing the at least one metallization, for example by etching.

According to at least one embodiment, the spacers are coated with the solder partially or completely all around and over the entire surface.

According to at least one embodiment, the plates are held together only via the solder. This means that additional mechanical, load-bearing, fixed connections between the plates can be omitted.

### BRIEF DESCRIPTION OF THE DRAWINGS

In the following, an optoelectronic component described herein and a manufacturing method described herein are explained in more detail with reference to the drawings by means of exemplary embodiments. Identical reference signs specify identical elements in the individual figures. However, no references to scale are shown, rather individual elements may be shown exaggeratedly large for better understanding.

In the Figures:

FIG. 1 shows a schematic sectional view of an exemplary embodiment of a component;

FIG. 2 shows a schematic sectional view of a further exemplary embodiment of a component described here;

FIG. 3 shows a schematic sectional view of a further exemplary embodiment of a component described herein;

FIG. 4 shows a schematic sectional view of a base for components described herein;

FIG. 5 shows a schematic bottom view of a base for components described herein;

FIG. 6 shows a schematic bottom view of an optoelectronic semiconductor device for components described here;

FIG. 7 shows a schematic sectional view of an optoelectronic semiconductor device for components described herein;

FIG. 8 shows a schematic sectional view of an optoelectronic semiconductor device for components described here;

FIG. 9 shows a schematic sectional view of a component described here on an external carrier;

FIG. 10 shows a schematic perspective view of a method step for manufacturing components described herein;

FIG. 11 shows a schematic sectional view of a method step for manufacturing components described here;

FIGS. 12 and 13 show schematic plan views of method steps for manufacturing components described here;

FIGS. 14 and 15 show schematic sectional views of method steps for manufacturing components described here;

FIG. 16 shows a block diagram of manufacturing processes for components described herein;

FIG. 17 shows a schematic sectional view of a further exemplary embodiment of a component described herein; and

FIGS. 18 to 20 show schematic sectional views of bases for components described herein.

### DETAILED DESCRIPTION OF ILLUSTRATIVE EMBODIMENTS

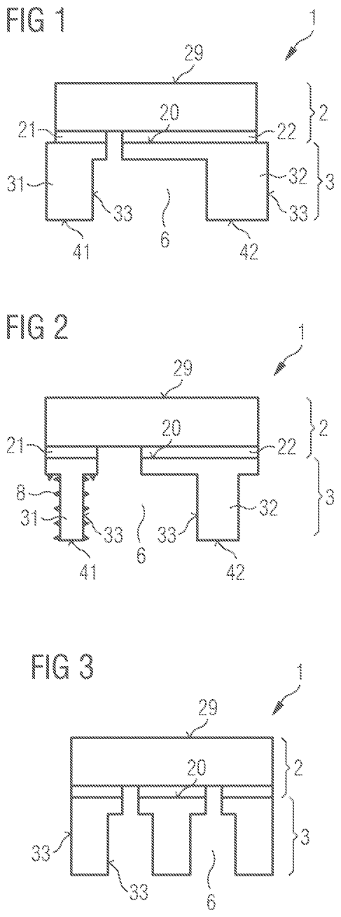

FIG. 1 shows an exemplary embodiment of an optoelectronic component 1. The component 1 comprises an optoelectronic semiconductor device 2 and a base 3.

The semiconductor device 2 is, for example, a light-emitting diode or a photodetector. The semiconductor device 2 preferably contains a semiconductor chip not shown in FIG. 1. The semiconductor chip is surrounded in particular by a housing. Furthermore, the semiconductor device 2 comprises a first electrical contact surface 21 and a second electrical contact surface 22. The contact surfaces 21, 22 are located in an assembly side 20 of the semiconductor device 2. The assembly side 20 is opposite to a light exit side 29 and/or a light entrance side. Between the contact surfaces 21, 22 there is a preferably narrow parting line in the direction parallel to the assembly side 20.

The base 3 is formed by a first intermediate piece 31 and by a second intermediate piece 32. The intermediate pieces 31, 32 comprise the same thickness. Furthermore, the intermediate pieces 31, 32 are preferably attached directly to the contact surfaces 21, 22 by means of soldering. There is then only a solder between the contact surfaces 21, 22 and the intermediate pieces 31, 32.

Seen in cross-section, the intermediate pieces 31, 32 are each L-shaped. Thus, the intermediate pieces 31, 32 comprise a recess 6. The recess 6 does not extend as far as the contact surfaces 21, 22. The intermediate pieces 31, 32 are formed asymmetrically to each other. Thus, the second intermediate piece 32 comprises a larger extension in the direction parallel to the assembly side 20 at the larger contact surface 22. The regions of the intermediate pieces 31, 32 not affected by the recess 6 can be of the same width, as illustrated in FIG. 1, or deviating therefrom can also comprise different extensions in the direction parallel to the assembly side 20.

On bottom sides facing away from the semiconductor device 2, the intermediate pieces 31, 32 each form connection surfaces 41, 42. The component 1 can be electrically contacted externally via the connection surfaces 41, 42, preferably by means of soldering.

Side surfaces 33 of the intermediate pieces 31, 32 are exposed. In particular, the intermediate pieces 31, 32 are not embedded in a plastic body or potting body. It is possible that a solder or an electrically conductive adhesive with which the base 3 is attached to the semiconductor device 2 extends to a small extent onto the side surfaces 33.

The base 3 allows the component 1 to be adjusted to a specific overall thickness with small tolerances, without having to adjust the semiconductor device 2. Thus, the component 1 can be used in a wide variety of applications. Thus, the base 3 forms an interposer with which the component 1 can be soldered to a flexible printed circuit board, for example.

In this case, a thickness tolerance is low. This is achieved by forming the base 3 by a lead frame, for example formed of copper or a copper alloy. In order to be able to process the base 3 efficiently by means of punching, the recess 6 is present in the intermediate pieces 31, 32. Otherwise, a combination of a narrow parting line between the intermediate pieces 31, 32 along the assembly side 20 and a relatively large thickness of the base 3 is not achievable. Thus, exclusively with punching techniques and etching techniques, the required low thickness tolerances are not achievable. The high accuracy of the base described here is made possible by the fact that it is manufactured from a profile-milled stepped strip.

FIG. 1 also illustrates that the intermediate pieces 31, 32 may project beyond the semiconductor device 2 along the assembly side 20. A projection of the base 3 over the semiconductor device 2 is, for example, at least 0.1 mm and/or at most 0.5 mm. At the parting line between the intermediate pieces 31, 32, the intermediate pieces 31, 32 preferably terminate flush with the contact surfaces 21, 22 within the manufacturing tolerances.

In FIG. 2, it is illustrated that the intermediate pieces 31, 32 are overall flush with the contact surfaces 21, 22, in the direction parallel to the assembly side 20. A corresponding arrangement may also be present in FIG. 1.

In addition, it is shown in FIG. 2 that the intermediate pieces 31, 32 can be T-shaped. Thus, the intermediate pieces 31, 32 comprise a recess 6 on both sides of a region of maximum thickness. At side edges of the semiconductor device 2, the intermediate pieces 31, 32 may thus comprise a reduced thickness. The same may be the case in all other exemplary embodiments.

Furthermore, it is illustrated in FIG. 2 that milling traces 8 can be present on the base 3. Such milling traces 8 are formed, for example, by grooves or small burrs. The milling traces 8 are drawn only on the first intermediate piece 31 in FIG. 2, but are preferably found on all intermediate pieces 31, 32. Such milling traces 8 could also be present in all other exemplary embodiments of the component 1.

According to Figure 3, the semiconductor device 2 comprises more than two contact surfaces. Accordingly, more than two intermediate pieces of the base 3 are present.

It is possible that the intermediate pieces have different shapes. For example, T-shaped and L-shaped intermediate pieces may be present in the base 3 in combination with each other.

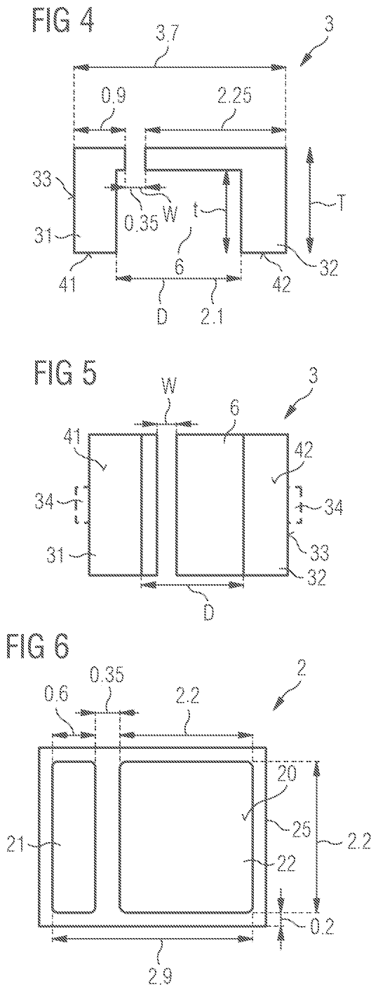

FIG. 4 shows an example of a base 3. According to FIG. 4, the base 3 comprises a thickness T. For example, the thickness T is 1.635 mm. A distance W between the intermediate pieces 31, 32, i.e., a width of the parting line, is comparatively small and is only 0.35 mm. Thus, a quotient of the thickness T and the distance W is approximately 5.

In order to be able to work the base 3 by means of punching, the recesses 6 are formed in the intermediate pieces 31, 32. A depth t of the recesses 6 is preferably at least 60% or 70% or 50% and/or at most 90% or 85% or 80% of the thickness T of the base 3. This is preferably also true in all other exemplary embodiments.

A distance D between the L-shaped or T-shaped legs of the intermediate pieces 31, 32 is preferably approximately at the thickness T of the base 3. For example, the distance D is greater than the thickness T by at least a factor of 1.1 or 1.2 and/or by at most a factor of 1.6 or 1.4 in order to ensure efficient punching.

The dimensions illustrated by way of example in FIG. 4, which are specified in mm, may also apply in all other exemplary embodiments. Here, the respective dimensions, individually or in combination, may be present with a tolerance of at most a factor of 3 or 2 or 1.5. Pairwise quotients of the mentioned dimensions may be present, individually or in combination, according to the values of FIG. 4, for example each with a tolerance of at most a factor 1.5 or 1.3.

FIG. 5 shows a bottom view of the base 3. The recesses 6 preferably extend continuously and in a straight line in the direction parallel to outer edges of the intermediate pieces 31, 32.

As in all other exemplary embodiments, it is possible that one or more connecting webs 34 extend from each of the intermediate pieces 31, 32. The connecting webs 34 are preferably narrower than the intermediate pieces 31, 32. Deviating from the illustration according to Figure 5, the connecting webs 34 can also comprise the same width as the intermediate pieces 31, 32, in the direction parallel to the parting line between the intermediate pieces 31, 32. Such connecting webs 34 serve in particular to hold the intermediate pieces 31, 32 in a lead frame compound. Accordingly, such connecting webs 34 may also be present in all exemplary embodiments.

FIG. 6 illustrates a bottom view of an optoelectronic semiconductor device 2. The contact surfaces 21, 22 are preferably surrounded all around by a material of a housing 25. The housing 25 is, for example, made of a plastic.

The dimensions shown by way of example in FIG. 6 may also apply individually or in combination preferably with a tolerance of at most a factor of 3 or 2 or 1.5. Also quotients of the dimensions may apply with a corresponding tolerance individually or in combination.

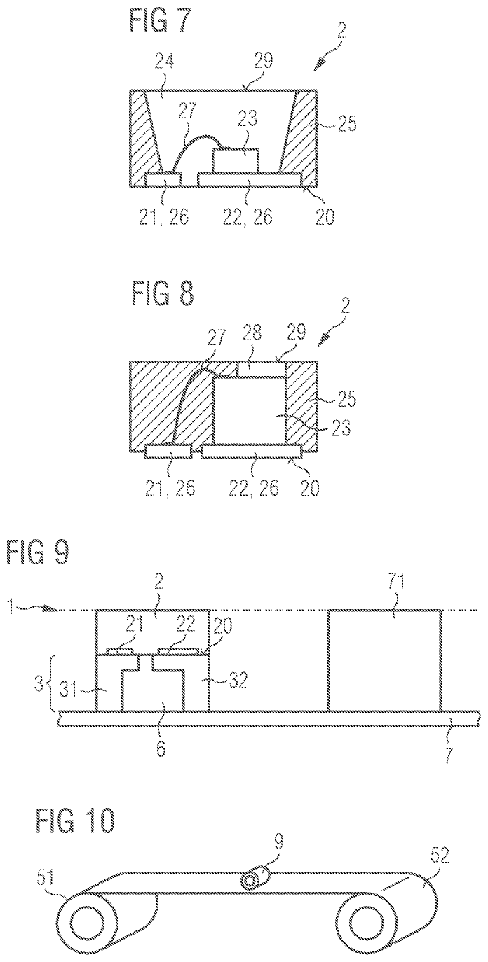

FIGS. 7 and 8 illustrate examples of semiconductor devices 2. The semiconductor devices 2 each comprise a semiconductor chip 23, wherein a plurality of semiconductor chips may be present. The semiconductor chips 23 are, for example, light emitting diode chips. It is possible that the semiconductor chips 23 are attached to the contact surfaces 21, 22 via bonding wires 27. The contact surfaces 21, 22 are preferably part of a lead frame 26 of the semiconductor device 2.

Optionally, a phosphor body 28 can be arranged downstream of the semiconductor chip 23, see FIG. 8. The phosphor body 28 can be used, for example, to generate white light from blue light.

Furthermore, the semiconductor devices 2 each comprise a housing 25. The housing 25 is made of a white material, for example. According to Figure 7, the semiconductor chip 23 is located in a cutout of the housing 25. The cutout 25 may be partially or completely filled with a potting material 24, wherein the potting material 24 may contain a phosphor. In contrast, according to FIG. 8, the housing 25 is molded directly to the semiconductor chip 23 and to the optional phosphor 28.

According to FIG. 7, the contact surfaces 21, 22 are flush with the housing 25 in the direction away from the semiconductor chip 23. The semiconductor device 2 can be designed as a QFN device. Optionally, see FIG. 8, it is possible for the contact surfaces 21, 22 to protrude partially or even completely from the housing 25.

In FIG. 9 it is illustrated that the component 1 is mounted on an external carrier 7. A further semiconductor device 71 is also mounted on the carrier 7. The carrier 7 is, for example, a flexible circuit board, also referred to as a flex PCB, or also a rigid circuit board in a mobile device such as a cell phone. The component 2 is, for example, a flash light.

Due to the base 3, the component 1 as well as the further semiconductor device 71 comprise the same overall height above the external carrier 7 with a high precision.

In FIGS. 10 to 14, a manufacturing method for the components 1 is illustrated. Referring to FIG. 10, a roll-to-roll method is used to mill a metal sheet 51 into a lead frame blank 52, using a milling tool 9. The milling tool 9 is used to create the recesses 6, not drawn in FIG. 10.

Optionally, the milling tool 9 can also be used to set a thickness of the metal sheet 51 and thus of the lead frame blank 52 with a small tolerance.

FIG. 11 illustrates that the intermediate pieces 31, 32 are preferably also produced in a roll-to-roll method by means of punching. In this process, the intermediate pieces 31, 32 still remain mechanically connected to one another via the connecting webs 34.

Likewise, at least one metallization 4 can be applied in a roll-to-roll method. The metallization 4 can cover the entire surface of the intermediate pieces 31, 32.

Due to the metallization 4, the connection surfaces 41, 42 as well as sides of the intermediate pieces 31, 32 facing away from the connection surfaces 41, 42 can preferably be made solderable. This is achieved, for example, by the metallization 4 comprising a relatively thick gold partial layer as an outermost partial layer.

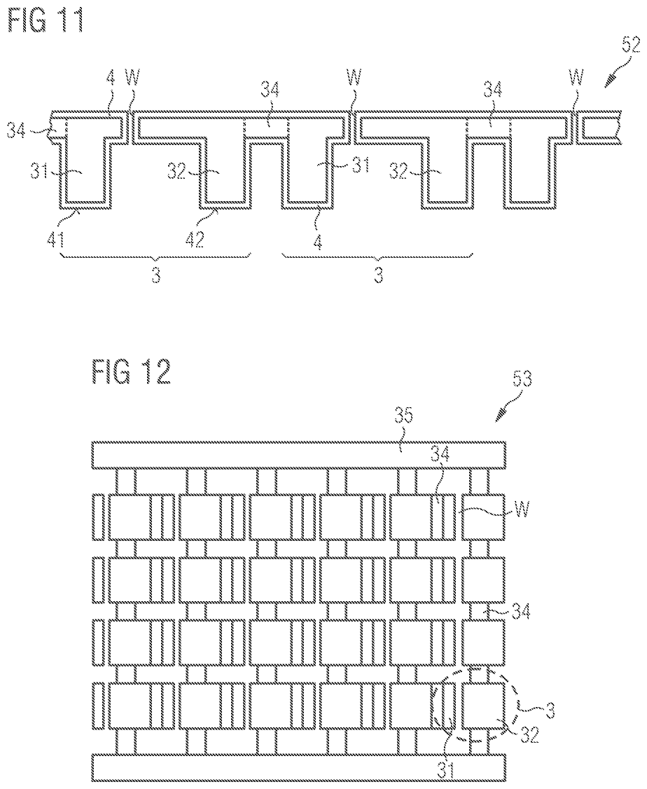

According to FIG. 12, a lead frame compound 53 is produced from the lead frame blank 32. In the lead frame compound 53, the individual intermediate pieces 31, 32 are mechanically connected to one another via the connecting webs 34. A plurality of lead frame compounds 53 are preferably produced from the lead frame blank 52.

The connecting webs 34 in a direction perpendicular to strips 35 at the edge of the lead frame compound 53 preferably comprise the same thickness as the intermediate pieces 31, 32 in the region of the recesses 6, as the connecting webs 34 extending parallel to the strips 35 and/or as the strips 35 themselves. It is possible for the connecting webs 34 running perpendicular to the strips 35 and thus perpendicular to the recesses 6 to be brought to the desired thickness in a second milling step or alternatively in an etching step.

Thus, two milling operations offset by 90° can be carried out in order to bring the recesses 6 and the connecting webs 34 running parallel to the strips 35 to the desired thickness on the one hand and the connecting webs 34 running perpendicular to the recesses 6 to the desired thickness on the other hand.

Structuring by means of punching is particularly preferably carried out only after all regions of the lead frame blank 52 have been brought to the desired thickness.

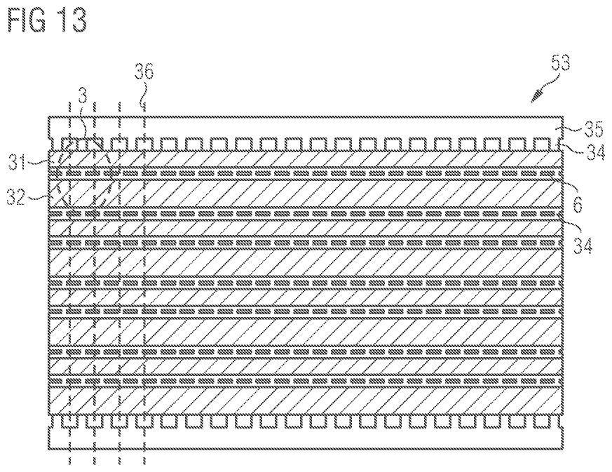

FIG. 13 shows a further option for the lead frame compound 53. Milling is carried out only in the direction parallel to the strips 35 and thus only along a single direction. Thus, milling traces preferably extend parallel to the strips 35. Areas where the thickness has not changed as a result of milling or in which only one thickness has been corrected are shown hatched in FIG. 13.

Partitioning between adjacent bases 3 in a direction parallel to the strips 35 is carried out along separation lines 36. The separation lines 36 thus run perpendicular to the strips 35. This partitioning along the separation lines 36 is carried out, for example, by means of sawing or etching.

In the region of reduced thickness, the parting lines between the intermediate pieces 31, 32 are punched and the connecting webs 34 to the individual bases 3 are cut, for example also by means of punching. This is symbolized schematically by dashed lines in FIG. 13.

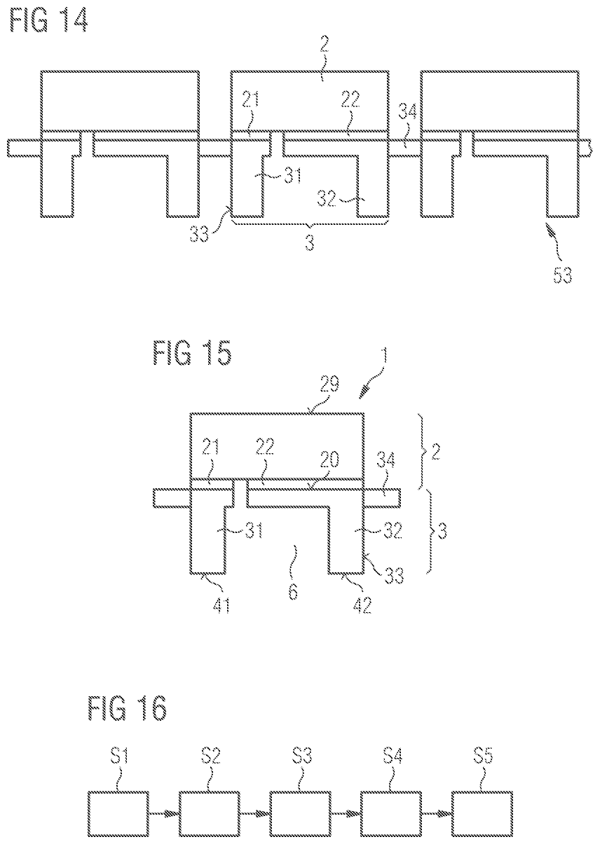

FIG. 14 illustrates that the semiconductor devices 2 are preferably applied to the respective bases 3 in the lead frame compound 53. The connecting webs 34 are preferably still intact.

In a subsequent step, the finished components 1 are separated, see FIG. 15, whereby residues of the connecting webs 34 may remain on the intermediate pieces 31, 32.

FIG. 16 shows a schematic block diagram of the method of manufacturing. In method step S1, the metal sheet 51 is profile milled. The metal sheet 51 is preferably a stepped strip of copper.

In method step S2, the intermediate pieces are produced by punching or by means of an alternative shaping process.

In optional step S3, metallization is applied, for example by electroplating partial layers of nickel, palladium and gold onto the lead frame blank 52.

According to method step S4, the lead frame blank 52 is cut to form the lead frame compounds 53. This can be realized by a reel-to-strip method.

According to step S5, the intermediate pieces are assembled with the semiconductor devices 2 and, subsequently, the components 1 are optionally tested and separated to form the finished, optionally tested components 1.

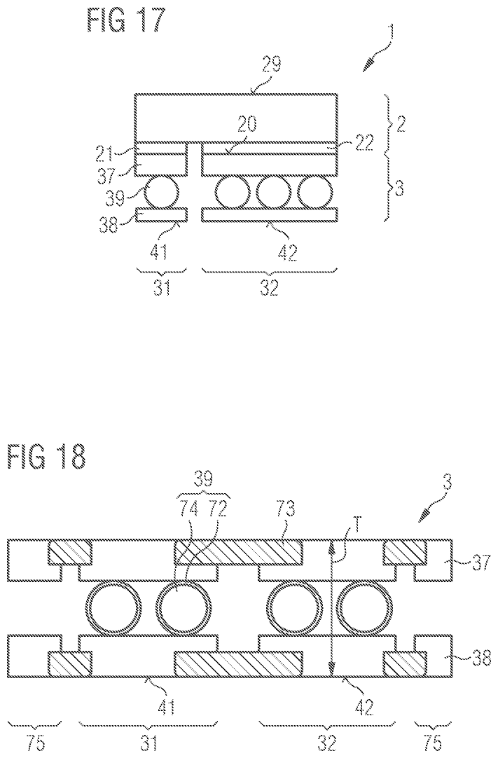

FIG. 17 shows a further exemplary embodiment of the component 1. The base 3 is formed by a composite lead frame 37, 38, 39. Thus each of the intermediate pieces 31, 32 comprises a cover plate 37, a bottom plate 38 and preferably several spacers 39. The cover plates 37, the bottom plates 38 and the spacers 39 are in particular each made of copper or a copper alloy. A connection between the cover plates 37, bottom plates 38 and spacers 39 within the intermediate pieces 31, 32 is realized, for example, by means of soldering.

The cover plates 37 and the bottom plates 38 are in particular made of rolled sheets and can thus be manufactured precisely with respect to their thickness. At the same time, the cover plates 37 and the bottom plates 38 are comparatively thin, so that the cover plates 37 and the bottom plates 38 can be worked by means of etching and/or punching. For example, a thickness of the cover plates 37 and the bottom plates 38 is at least 0.1 mm or 0.2 mm and/or at most 0.6 mm or 0.4 mm. For example, thickness tolerances of the cover plates 37 and the bottom plates 38 are each at most 10 μm or 20 μm.

In order to nevertheless realize a sufficient overall thickness of the base 3 despite the relatively thin cover plates 37 and bottom plates 38, the spacers 39 are arranged. The spacers 39, which are in particular spherical, may comprise comparatively large diameters, for example at least 0.2 mm or 0.4 mm and/or at most 1 mm or 0.8 mm. The spacers 39 may comprise a larger diameter than the cover plates 37 and bottom plates are thick. Alternatively, the spacers 39 may be cylindrical or cuboidal. The spacers 39 are also provided only with small diameter tolerances, for example with a diameter tolerance of at most 20 μm or 10 μm. Thus, the overall thickness T of the base 3 is precisely adjustable, as in the preceding exemplary embodiments.

FIG. 18 illustrates another design possibility of the base 3. The cover plates 37 and the bottom plates 38 are semi-etched and joined together with at least one molded body 73, for example made of a plastic. For this purpose, the cover plates 37 and the bottom plates 38 are etched in a first etching step in such a way that the regions for the molded bodies 73 are created. Then the molded bodies 73 are created. This is followed by complete etching between the intermediate pieces 31, 32. Thus, the molded bodies 73 are thinner than the cover plates 37 and than the bottom plates 38. Subsequently, the spacers 39 can be inserted and the cover plates 37 and the bottom plates 38 can be joined together.

The spacers 39 are preferably core-shell balls. Cores 74 are preferably copper spheres. Shells 72 are in particular formed by a solder coating. Such spacers 39 may also be used in all other exemplary embodiments.

Optionally, edge regions 75 may be located adjacent the intermediate pieces 31, 32. The edge regions 75 can be free of the spacers 39 or, in deviation from FIG. 18, comprise spacers 39. However, the edge regions 75 are preferably removed, different than illustrated in FIG. 18.

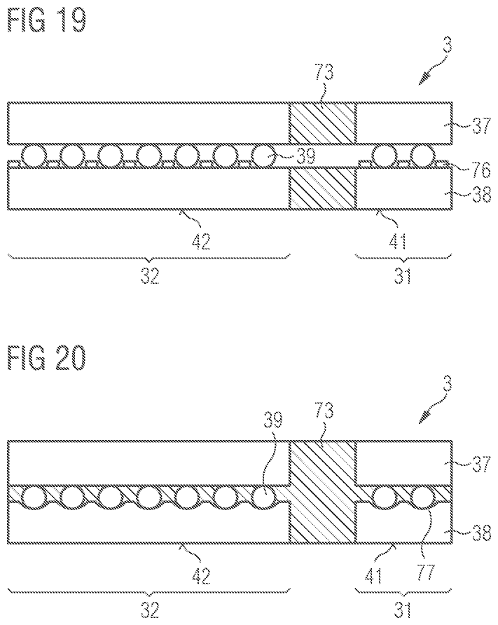

In the case of the base 3 of FIG. 19, the molded bodies 73 are of the same thickness as the cover plates 37 and the bottom plates 38. For example, the cover plates 37 and the bottom plates 38 are structured by punching or etching in a lead frame compound, and subsequently the molded bodies 73 are produced by injection molding and/or pressing.

To place the spacers 39 in defined positions, a mask layer 76 may be provided. Other than illustrated, the mask layer 76 may be attached to both the cover plates 37 and the bottom plates 38. For example, the mask layer 76 is a photoresist. The mask layer 76 may be removed after the spacers 39 are attached or may still be present in the finished components 1.

In FIG. 20, it is illustrated that the molded body 73 may fill an area between the cover plates 37 and the bottom plates 38. For positioning the spacers 39, a plurality of depressions 77 are formed in the cover plates 37 and/or in the bottom plates 38, for example in the form of spherical segments or in the form of cylindrical holes.

In particular, a degree of coverage of the cover plates 37 and the bottom plates 38 with the spacers 39 can be adjusted via the depressions 77 or via the mask layer 76. Thus, short circuits between adjacent cover plates 37 and bottom plates 38 can be prevented via the spacers 39. In addition, this allows high thermal conductivity to be realized in the direction perpendicular to the assembly side in areas of high surface density of the spacers 39. Such areas of high surface density are present in particular centrally in the intermediate pieces 31, 32, especially across the larger intermediate piece 32. Towards an edge, the spacers 39 can be arranged with a lower surface density.

Such depressions 77 or mask layers 76 can be present in the same way in the other exemplary embodiments of the base 3 as a composite lead frame 37, 38, 39.

In FIGS. 17 to 20, thin metal sheets are used as cover plates 37 and as bottom plates 38, respectively. However, it is conceivable to use other thin components alternatively. For example, instead of being formed by metal sheets, the cover plates 37 and the bottom plates 38 can also be formed by thin printed circuit boards, metal core boards, or ceramic circuit boards. Such components, if their overall thickness is small, are likewise available with comparatively small thickness tolerances and can be joined together in the same way by means of the spacers 39.

In all other respects, the explanations of FIGS. 1 to 16 apply mutatis mutandis to FIGS. 17 to 20.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

1.-19. (canceled)

20. A method for manufacturing optoelectronic components, wherein each component comprises an optoelectronic semiconductor device including at least two electrical contact surfaces on an assembly side, a lead frame base and electrical connection surfaces for external electrical contacting of the semiconductor device, wherein each base comprises at least two metallic intermediate pieces, wherein each of the intermediate pieces is fastened directly to one of the contact surfaces, and the intermediate pieces are each L-shaped or T-shaped as seen in cross-section perpendicular to an associated assembly side, wherein the electrical connection surfaces are formed by bottom sides of the intermediate pieces facing away from the semiconductor device, and wherein a quotient of a thickness of the intermediate pieces and a distance between the intermediate pieces in a direction parallel to the assembly side is between 3 and 20 inclusive, the method comprising:
providing a metal sheet;
milling the metal sheet;
structuring the metal sheet into a lead frame blank with the intermediate pieces;
applying a plurality of semiconductor devices to the intermediate pieces; and
separating to form the components.

21. The method according to claim 20, wherein side surfaces of the intermediate pieces are exposed.

22. The method according to claim 20, each intermediate piece is made a bulk material.

23. The method according to claim 20, wherein the intermediate pieces are each T-shaped when viewed in cross-section perpendicular to the assembly side, and wherein the distance is between 0.1 mm and 0.7 mm inclusive.

24. The method according to claim 20, wherein the intermediate pieces are L-shaped when viewed in cross-section perpendicular to the assembly side, and wherein a quotient of the thickness of the intermediate pieces and a distance between legs of the L's extending away from the assembly side is between 0.4 and 3 inclusive.

25. The method according to claim 20, wherein the distance is between 0.1 mm and 0.7 mm inclusive.

26. The method according to claim 20, wherein milling comprises profile milling such that, at least some of the intermediate pieces, each comprises at least one recess after milling.

27. The method according to claim 20, further comprising applying at least one metallization to the lead frame blank.

28. The method according to claim 27, further comprising, after applying the at least one metallization to the lead frame blank, dividing the lead frame blank into lead frame compounds, wherein milling the metal sheet, structuring the metal sheet and applying the at least one metallization to the lead frame blank comprises performing a roll-to-roll process.

29. (canceled)

30. The method according to claim 20, wherein milling comprises performing milling only on one side of the metal sheet, and wherein milling traces are still visible on the intermediate pieces after separating.

31. The method according to claim 20, wherein structuring the metal sheet comprises punching the metal sheet.

32. The method according to claim 20, wherein the contact surfaces are applied congruently to the intermediate pieces so that the contact surfaces and the intermediate pieces are of the same size when viewed in plan view.

33. The method according to claim 20, wherein the metal sheet is made of copper or of a copper alloy.

34. The method according to claim 20, wherein the semiconductor devices are light emitting diodes and/or photodetectors.

35. The method according to claim 20, further comprising placing the components on an external carrier, wherein the external carrier is a rigid or a flexible printed circuit board.

36. The method according to claim 35, wherein further comprising applying at least one further semiconductor device to the external carrier, and wherein the component is as thick as the further semiconductor device due to the base with a tolerance of at most 40 μm.

37. A method for manufacturing optoelectronic components, wherein each component comprises an optoelectronic semiconductor device including at least two electrical contact surfaces on an assembly side, a lead frame base and electrical connection surfaces for external electrical contacting of the semiconductor device, wherein each base comprises at least two metallic intermediate pieces, wherein each of the intermediate pieces is fastened directly to one of the contact surfaces, wherein each of the intermediate pieces comprises a cover plate, a bottom plate and spacers located there between so that each base is a composite lead frame, wherein each spacer is formed by metal cores provided with a continuous solder coating, wherein each of the electrical connection surface is formed by bottom sides of the intermediate pieces facing away from the semiconductor device, and wherein a quotient of a thickness of the intermediate pieces and a distance between the intermediate pieces inside the components in a direction parallel to the assembly side is each between 3 and 20 inclusive, the method comprising:
structuring the cover plates and the bottom plates for the intermediate pieces;
providing the spacers and connecting the spacers to the cover plates and the bottom plates;
applying a plurality of semiconductor devices on the intermediate pieces; and
separating to form the components.

38. The method according to claim 37, further comprising mechanically connecting the cover plates and the bottom places to each other by at least one molded body, wherein the molded body is formed of a plastic, and wherein the at least one molded body is a part of a finished base.

39. The method according to claim 20,
wherein a thickness of the metal sheet after milling is between 0.3 mm and 3 mm inclusive, and
wherein a variation around the thickness is at most 30 μm.
